(19) United States
(12) Patent Application Publication
(10) Pub. No.: US 2013/0169294 A1
(43) Pub. Date: Jul. 4, 2013

(54) DEVICES AND METHODS HAVING CAPACITANCE SENSE STRUCTURE FORMED OVER HOUSING SURFACE

(71) Applicants: Michael Bollesen, San Jose, CA (US); David G. Wright, San Diego, CA (US)

(72) Inventors: Michael Bollesen, San Jose, CA (US); David G. Wright, San Diego, CA (US)

(73) Assignee: CYPRESS SEMICONDUCTOR CORPORATION, San Jose, CA (US)

(21) Appl. No.: 13/340,349

(22) Filed: Dec. 29, 2011

(51) Int. Cl. G01R 27/26

(52) U.S. Cl. 324/658

(57) ABSTRACT

A capacitance sensing system can include at least a first conductive pattern formed on a first surface of a housing of an electronic device; and a capacitance sensing circuit electrically connected to the first conductive pattern.

### TECHNICAL FIELD

The present disclosure relates generally to electronic devices input systems, and more particularly to capacitance sensing systems.

### BACKGROUND

Electronic devices and systems can include input devices having a generally flat surface to enable cursor type control inputs. In particular, laptop computers typically include a touchpad assembly positioned adjacent to a keyboard, which can operate as a substitute for a pointing device, such as a mouse. Touchpads can utilize capacitance or resistance sensing to sense user inputs.

FIG. 26 is an exploded view of a conventional laptop computer 2600. A conventional laptop computer 2600 can include a display 2605, a top housing portion 2603 and a bottom housing portion (not shown). A top housing portion 2603 can include openings 2605 to accommodate a separate touchpad assembly 2601 in a palm rest area 2607.

FIG. 27 is an exploded view of another conventional laptop computer 2700. Conventional laptop computer 2700 can include a palm rest assembly 2707 having a housing 2703 with a touchpad assembly 2701 connected thereto. Touchpad assembly 2701 can extend through openings formed in the housing 2703.

Conventionally, sensing electrodes of a touchpad assembly 2701 can be formed from traces on a printed circuit board (PCB) contained within a touchpad assembly.

### BRIEF DESCRIPTION OF THE DRAWINGS

FIG. 1 is a side cross sectional view of a capacitance sensing system according to an embodiment.

FIG. 2 is a side cross sectional view of a capacitance sensing system according to another embodiment.

FIG. 3 is a side cross sectional view of a capacitance sensing system according to a further embodiment.

FIG. 4 is a side cross sectional view of a capacitance sensing system according to another embodiment.

FIG. 5 is a side cross sectional view of a capacitance sensing system according to another embodiment.

FIG. 6 is a side cross sectional view of a capacitance sensing system according to another embodiment.

FIG. 7 is a diagram showing a method of making a capacitance sensing system by ink jet printing according to an embodiment.

FIGS. 8A to 8C are a series of side cross sectional views showing a method of capacitance sensing system by screen printing according to an embodiment.

FIGS. 9A to 9D are a series of side cross sectional views showing a method of making a capacitance sensing system by pad printing according to an embodiment.

FIGS. 10A and 10B are side cross sectional views showing a method of making a capacitance sensing system with a subtractive process according to an embodiment.

FIGS. 11A and 11B are side cross sectional views showing a method of making a capacitance sensing system with a pre-formed conductive pattern according to an embodiment.

FIGS. 12A to 12C are a series of side cross sectional views showing a method of making a capacitance sensing system with a pre-formed conductive pattern according to a further embodiment.

FIGS. 13A and 13B are side cross sectional views showing a method of making a capacitance sensing system with a pre-formed conductive pattern according to another embodiment.

FIGS. 14A and 14B are side cross sectional views showing a method of making a capacitance sensing system with a pre-formed conductive pattern according to another embodiment.

FIG. 15 is a top plan view of a single layer conductive pattern that can be included in embodiments.

FIG. 16 is a top plan view of a further single layer conductive pattern that can be included in embodiments.

FIG. 17 is a top plan view of another single layer conductive pattern that can be included in embodiments.

FIGS. 18A to 18D are a series of side cross sectional views showing a method of making a capacitance sensing system with multiple conductive patterns according to embodiments.

FIGS. 19A to 19C are top plan views showing a method of making a capacitance sensing system with multiple conductive patterns according to an embodiment.

FIGS. 20A and 20B are top plan views of a multiple layer conductive pattern that can be included in embodiments.

FIGS. 21A and 21B are top plan views of a further multiple layer conductive pattern that can be included in embodiments.

FIGS. 22A and 22B are top plan views of another multiple layer conductive pattern that can be included in embodiments.

FIGS. 23A to 23C are diagrams showing a connection between a conductive pattern and capacitance sensing circuits according to an embodiment.

FIGS. 24A to 24D are diagrams showing connections between a conductive pattern and capacitance sensing circuits according to various other embodiments.

FIGS. 25A to 25I are diagrams of electronic systems according to various embodiments.

FIG. 26 is an exploded view of a conventional laptop computer having a touch pad.

FIG. 27 is an exploded view of another conventional laptop computer having a touch pad.

### DETAILED DESCRIPTION

Various embodiments will now be described that include capacitance sensing structures and methods that can enable a capacitance sensing area to be formed on a surface of the housing (or some other assembly surface) of an electronic device.

In the various embodiments shown below, like items are referred to by the same reference character.

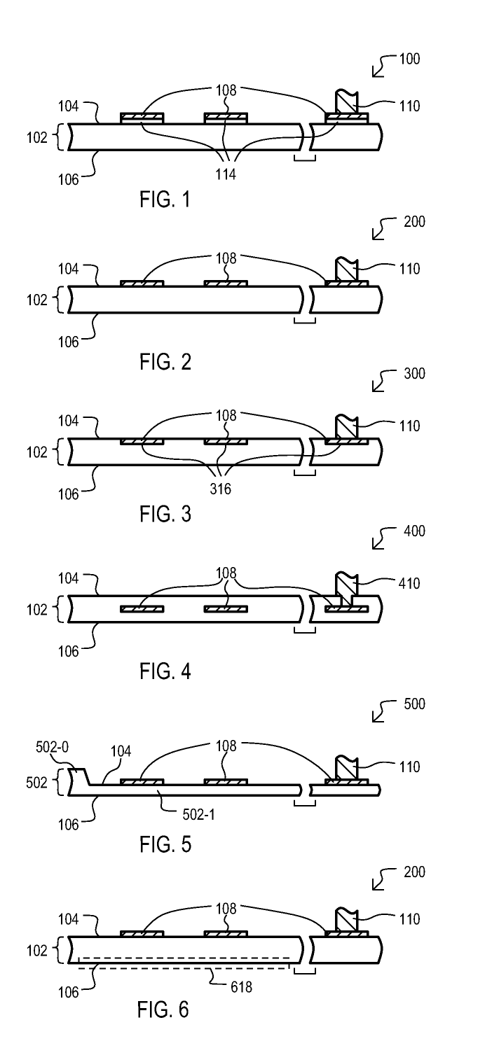

Referring now to FIG. 1, a capacitance sensing system 100 according to an embodiment is shown in a side cross sectional view. A capacitance sensing system 100 can include a housing 102, a conductive pattern 108, and circuit connections 110 to the conductive pattern 108. A housing 102 can be a structure for containing components of an electronic or electrical device. In some embodiments, a housing 102 can be a molded or stamped structure. In one particular embodiment, a housing 102 can be a molded plastic structure. A housing 102 can have a first surface 104 and an opposing second surface 106. In one very particular embodiment, a first surface 104 can be an internal surface of a housing 102, while a second surface 106 can be an external surface of a housing 102.

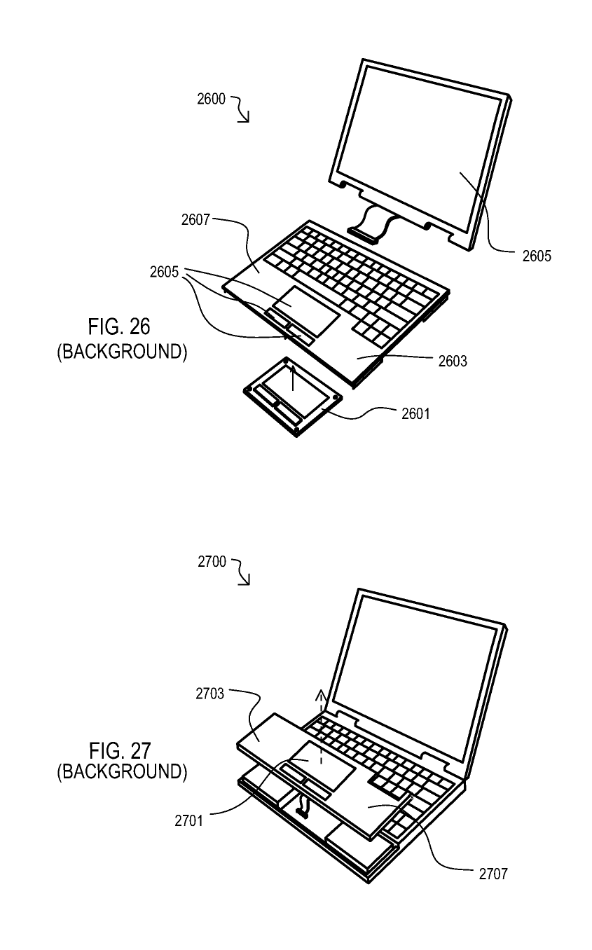

A conductive pattern 108 can be formed on a first surface 104. A conductive pattern 108 can generate variations in capacitance in response to the proximity of an object. This is in contrast to conventional approaches like those shown in FIGS. 26 and 27, in which sensing structures are circuit board traces (i.e., components protected by a housing). In the embodiment of FIG. 1, a conductive pattern 108 can be attached to a first surface by an intervening layer 114. In one very particular embodiment, an intervening layer can be an adhesive for mechanically attaching conductive pattern 108 to first surface 104.

A circuit connection 110 can provide a conductive connection to capacitance sensing circuits. In some embodiments, a circuit connection 110 can extend vertically from a first surface 104.

In one embodiment, a second surface 106 can be an input surface of an electronic device 100, with conductive pattern 108 sensing capacitance changes arising from objects proximate to, or contacting, the second surface 106. In a very particular embodiment, a second surface 106 can be a touch surface for detecting finger (or other object) touch positions.

Referring to FIG. 2, a capacitance sensing system 200 according to another embodiment is shown in a side cross sectional view. FIG. 2 differs from FIG. 1 in that a conductive pattern 108 can be formed directly on a first surface 104. That is, there is no intervening layer (114 in FIG. 1).

Referring to FIG. 3, a capacitance sensing system 300 according to another embodiment is shown in a side cross sectional view. FIG. 3 differs from FIG. 1 in that a conductive pattern 108 can be inset into a first surface 104. Accordingly, a first surface 104 can include insets 316 that receive and/or retain conductive pattern 108.

Referring to FIG. 4, a capacitance sensing system 400 according to a further embodiment is shown in a side cross sectional view. FIG. 4 differs from FIG. 1 in that a conductive pattern 108 can be formed within a housing 102, and hence have little or no surfaces exposed. In such an embodiment, circuit connections 410 can include portions that extend into housing 102 to contact conductive pattern 108. In addition or alternatively, conductive pattern 108 can include portions (not shown) that extend to first surface 104.

Referring to FIG. 5, a capacitance sensing system 500 according to yet another embodiment is shown in a side cross sectional view. FIG. 5 differs from FIG. 1 in that a housing 502 can include a first housing portion 502-0 that is thicker than a second housing portion 502-1. A conductive pattern 108 can be formed on a surface 104 of the second housing portion 502-1.

Referring to FIG. 6, a capacitance sensing system 600 according to another embodiment is shown in a side cross sectional view. FIG. 6 differs from FIG. 1 in that a second surface 106 can include user indications 618 formed thereon. User indications 618 can identify locations where capacitance sensing can occur, including a type of input and/or an area of input. User indications 618 can include any suitable indication type, including but not limited to: symbols or lines formed with paint, ink, surface etching, or decals; variations in surface texture, surface color, surface material; or an illuminated area, to name just a few examples.

It is noted that while FIGS. 1 to 6 have shown systems with a single conductive pattern, such systems can include additional conductive patterns formed over the one conductive pattern shown. Particular embodiments having multiple conductive patterns are shown in more detail below.

Having described various capacitance sensing system according to embodiments, methods of making such systems will now be described.

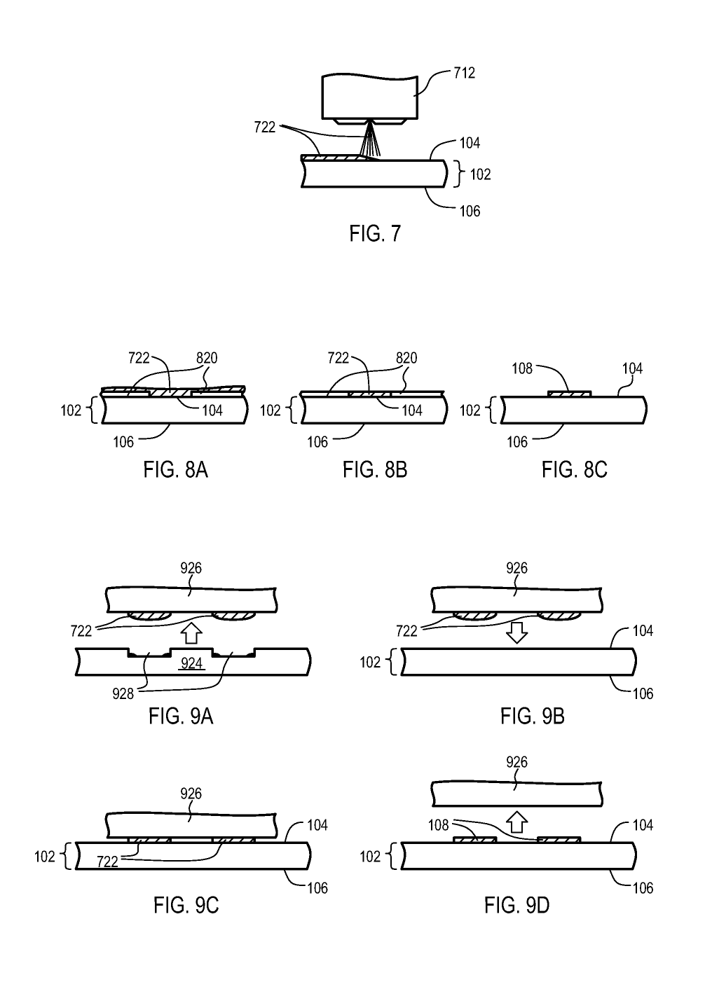

FIG. 7 shows an inkjet printing method according to an embodiment. An inkjet printer can include an inkjet nozzle 712 that prints a conductive ink (or paint) 722 onto a first surface 104 of a housing 102. Such a process can be an additive process as the conductive ink 722 can be printed in the desired conductive pattern shape. A conductive ink 722 can be any conductive ink suitable for providing the conductivity necessary for a desired capacitance sensing method. A conductive ink 722 can be a silver and/or carbon ink, as but two examples.

FIGS. 8A to 8C show a screen printing method according to an embodiment.

Referring to FIG. 8A, a screen 820 can be placed over a first surface 104 of a housing 102. A conductive ink (or paint) 722 can be placed over screen 722.

FIG. 8B shows the removal of excess conductive ink 722, which can leave conductive pattern 108 within openings of screen 820.

FIG. 8C shows the removal of the screen 820, leaving the conductive pattern 108 on first surface 104.

FIGS. 9A to 9D show a pad printing method according to an embodiment.

Referring to FIG. 9A, a pattern etching 928 can have etch openings 928 in the shape of a desired conductive pattern. Etch openings 928 can be initially filled with conductive ink (or paint) 722. A pad 926 can contact etch openings 928 to attract conductive ink 722 in the shape of the desired conductive pattern.

FIG. 9B shows the pad 926 being positioned over first surface 104 of housing 102. FIG. 9C shows pad 926 bringing conductive ink 722 into contact with first surface 104.

Referring to FIG. 9D, a pad 926 can be lifted from first surface 104, leaving a conductive pattern 108 on first surface 104.

While additive processes can be used to form a conductive pattern, in other embodiments, subtractive processes can be used. In a subtractive process, a conductive layer can be formed on a first surface. Subsequently, portions of the conductive layer can be removed to form the desired conductive pattern.

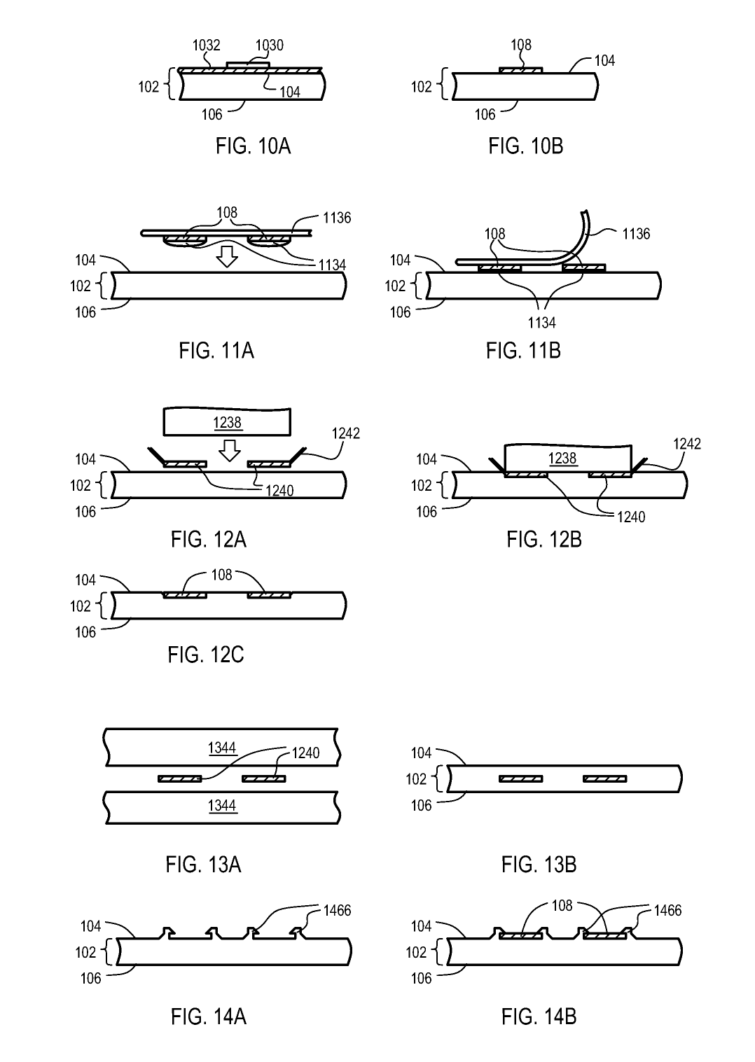

FIGS. 10A and 10B show one example of a subtractive process for forming a conductive pattern 108. Referring to FIG. 10A, a conductive layer 1032 can be formed over a first surface 104 (in this embodiment, directly on first surface 104). An etch mask 1030 can be formed on conductive layer 1032 having the shape of a desired conductive pattern. A conductive layer 1032 can be formed with any suitable method, including deposition, plating, or mechanical attachment, as but a few examples.

Referring to FIG. 10B, portions of conductive layer 1032 not covered by etch mask 1030 can be removed. Such etching can include wet chemical etching or plasma etching as but two examples.

It is noted that a subtractive process does not require an etch mask. For example, in other embodiments, different removal techniques can be used to create a conductive pattern. As but a few examples, portions of a conductive layer can be removed by laser removal or mechanical methods, such as cutting or scraping.

While some embodiments can pattern a conductive layer while it is over a first surface, other embodiments can utilize pre-fabricated conductive patterns. Examples of such embodiments will now be described.

FIGS. 11A and 11B show a method of forming a capacitance sensing system with a pre-fabricated conductive pattern.

Referring to FIG. 11A, a pre-formed conductive pattern 108 can be attached to a carrier 1136 on one side, and can have an adhesive 1134 formed on an opposing side. A pre-formed conductive pattern 108 can be formed according to any suitable method, including, but not limited to: cutting, etching, stamping, or printing.

Referring to FIG. 11B, adhesive 1134 on conductive pattern 108 can be brought into contact with first surface 104 of housing 102. A carrier 1136 can then be removed, leaving a conductive pattern 108 on the first surface 104.

FIGS. 12A to 12C show another embodiment in which a conductive pattern can be physically embedded into a housing surface. Referring to FIG. 12A, a pattern frame 1240 can be positioned between a housing 102 and a stamp 1238. A frame 1240 can include a desired conductive pattern, and may further include members 1242 that enable the frame 1240 to be physically positioned between stamp 1238 and housing 102. In particular embodiments, a stamp 1238, frame 1240 and/or housing 102 can be heated, to soften a first surface 104.

Referring to FIG. 12B, a stamp 1238 can force frame 1240 into a first surface 104. As shown in FIG. 12C, a stamp 1238 can be withdrawn, and members 1242 trimmed, resulting in a conductive pattern 108 formed in the first surface 104.

FIGS. 13A and 13B show an embodiment in which a conductive pattern can be physically embedded within a wall of a housing. Referring to FIG. 13A, a pattern frame 1240 can be positioned within an opening of a mold 1344. A material can then be injected into the mold 1344 to form a wall of a housing. Referring to FIG. 13B, after the material has cured, it can be removed from mold 1344. A resulting structure can have a conductive pattern 108 formed within a housing 102, between first and second surfaces (104 and 106).

FIGS. 14A and 14B show an embodiment in which a conductive pattern can be mechanically attached to a surface of a housing. Referring to FIG. 14A, mechanical members 1446 can be included for a housing 102. A prefabricated conductive pattern 108 can be mechanically attached to first surface 104 with such mechanical members. It is noted that while FIGS. 14A and 14B show mechanical members formed as part of a housing, other embodiments can include alternate mechanical members, including but not limited to: screws, clips, rivets, pegs, bosses, etc.

Conductive patterns according to embodiments herein can take various shapes. Particular embodiments single layer conductive patterns that can be included in embodiments will now be described.

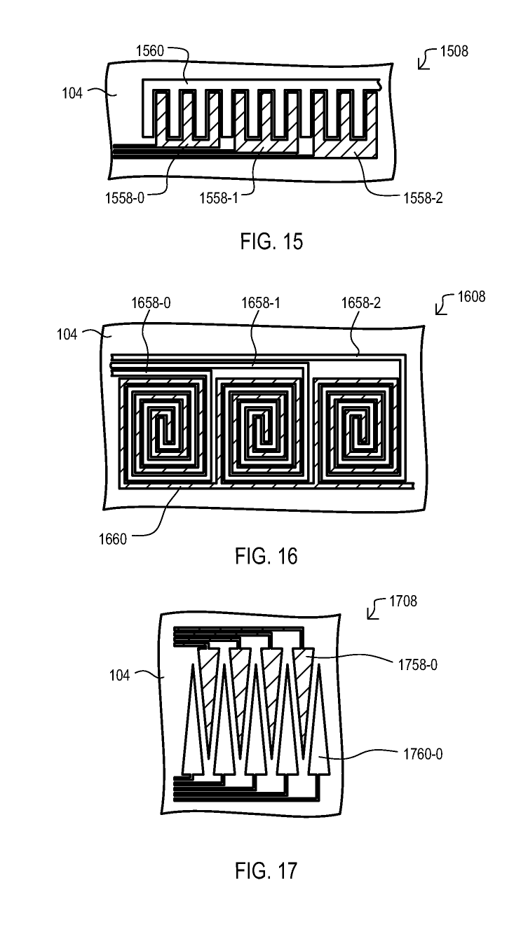

FIG. 15 shows a conductive pattern 1508 according to one embodiment. A conductive pattern 1508 can be formed on a housing surface 104 with one conductive layer. Conductive pattern 1508 can include a number of first electrodes 1558-0 to -2, having a same shape repeated in one direction. A second electrode 1560 can be interleaved with first electrodes (1558-0 to -2).

FIG. 16 shows another conductive pattern 1608 according to an embodiment. A conductive pattern 1608 can be formed on a housing surface 104 with one conductive layer. As in the case of FIG. 15, conductive pattern 1608 can include a number of first electrodes 1658-0 to -2, having a same shape repeated in one direction that are interleaved (in a spiral-like manner) with a second electrode 1660.

FIG. 17 shows another conductive pattern 1708 according to an embodiment. A conductive pattern 1708 can be formed on a housing surface 104 with one conductive layer. Conductive pattern 1708 can include first electrodes (one shown as 1758-0) repeated in one direction. In addition, second electrodes (one shown as 1760-0) can be repeated in the same direction.

It is understood that any of the conductive patterns shown in FIGS. 15-17 can be repeated in vertical and/or horizontal directions to cover a desired surface area. Further, while such embodiments can be formed with one conductive layer, in other embodiments, such patterns can be formed with more than one conductive layer. In addition, the conductive patterns of FIGS. 15-17 are intended to be but three examples of numerous conductive patterns that can be employed in capacitance sensing systems described herein.

As noted above, embodiments can include multiple conductive patterns formed over one another. Embodiments showing the formation of such structures will now be described.

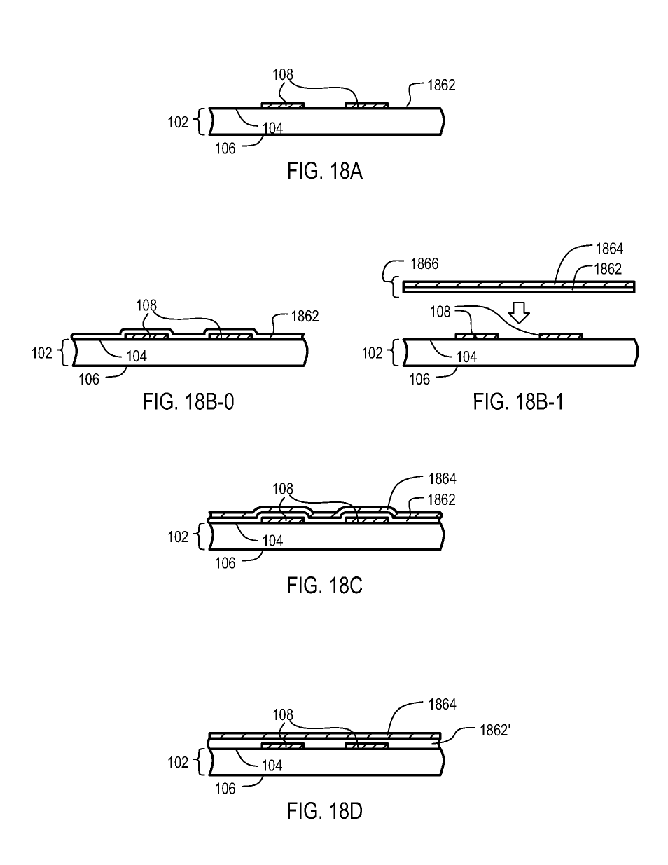

FIGS. 18A to 18D show a method forming a multi-layered capacitance sense structure according to embodiments.

Referring to FIG. 18A, a first conductive pattern 108 can be formed on a first surface of a housing 102 according to any of the embodiment shown herein, or equivalents.

Referring to FIG. 18B-0, an insulating layer 1862 can be formed over first conductive pattern 108. An insulating layer 1862 can be deposited or applied. An insulating layer 1862 can include any suitable material, including but not limited to, an insulating ink, paint, or other coating.

Referring to FIG. 18C, a second conductive pattern 1864 can be formed on an insulating layer 1862. A second conductive pattern 1864 can be formed using any of suitable technique described herein, or an equivalent.

FIGS. 18B-1 shows an alternate method to that shown in FIGS. 18B-0/18C.

Referring to FIG. 18B-1, an electrode structure 1866 can include an insulating layer 1862 attached to a pre-formed second conductive pattern 1864. In one particular embodiment, insulating layer 1862 can be, or can include, an adhesive material. Electrode structure 1866 can be brought into contact with a first surface 104 and first conductive pattern 108 to arrive at a structure like that of FIG. 18C.

The embodiments of FIGS. 18A to 18C show an arrangement in which an insulating layer 1862 and second conductive pattern 1864 can conform to a shape of a first conductive pattern 108. However, as shown in FIG. 18D, in other embodiments an insulating layer 1862′ may not be conformal, providing a substantially planar surface for second conductive pattern 1864.

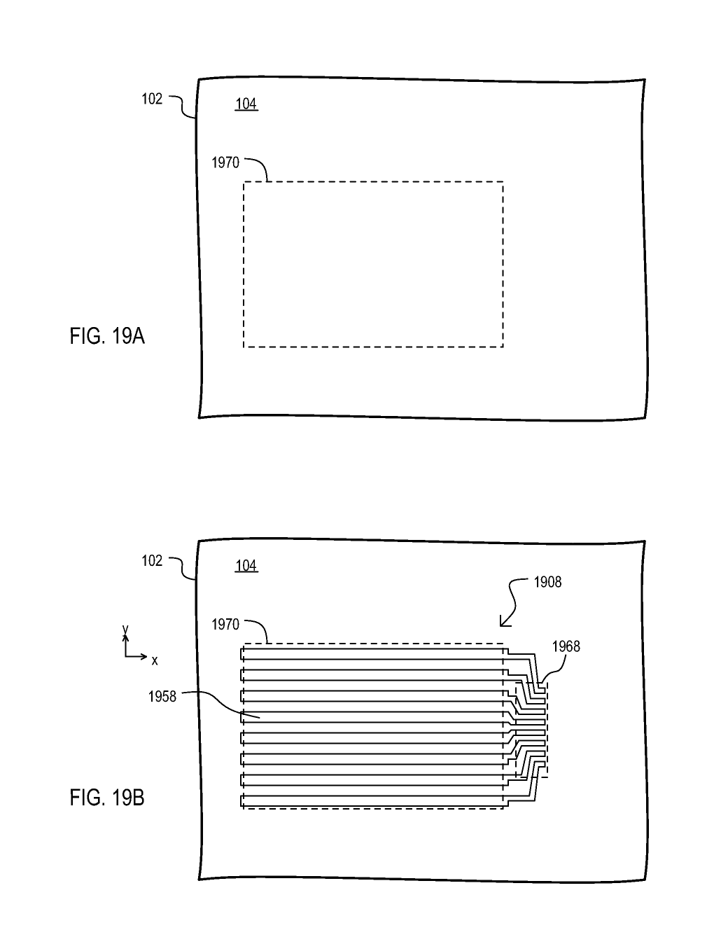

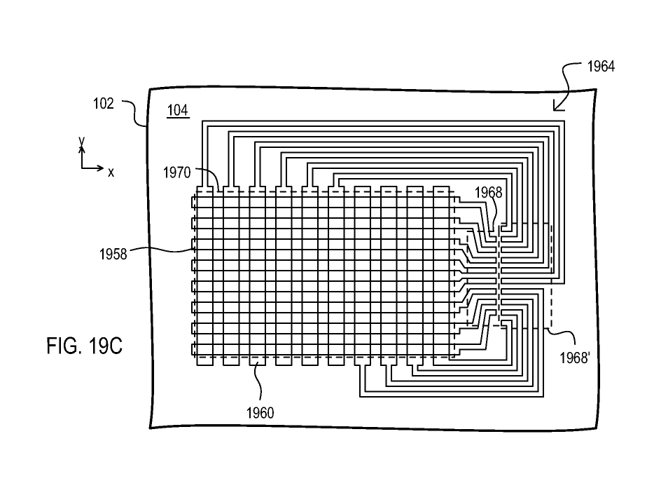

FIGS. 19A to 19C are a series of top plan views showing a method of making a capacitance sensing system according to a particular embodiment. Referring to FIG. 19A, an electrode area 1970 can be defined on a first surface 104 of a housing. An electrode area 1970 can be an area where capacitance sensors are to be placed. In some embodiments, a region opposite to electrode area 1970 (i.e., a region on a surface opposite to 104) can be a user input surface.

Referring to FIG. 19B, a first conductive pattern 1908 can be formed on a first surface 104 as described herein, or equivalents. In the embodiment shown, a first conductive pattern 1908 can include first electrodes (one shown as 1958) and first circuit connection portions 1968. First electrodes (e.g., 1958) can be repeated in a first direction (shown as “y”).

Referring to FIG. 19C, an insulating layer (not shown) can be formed over a first conductive pattern 1908. A second conductive pattern 1964 can be then be formed as described herein, or equivalents. In the embodiment shown, a second conductive pattern 1946 can include second electrodes (one shown as 1960) and second circuit connection portions 1968′. Second electrodes (e.g., 1960) can be repeated in a second direction (shown as “x”).

It is noted that while an insulating layer can be formed between first and second conductive patterns (1902 and 1964), such an insulating layer may not be formed over circuit connection portions 1968 (or can be subsequently removed from such portions) to ensure capacitance sensing circuits can have an electrical connection to the first conductive pattern 1908.

First and second circuit connection portions (1968 and 1968′) can provide connections to a capacitance sensing circuit.

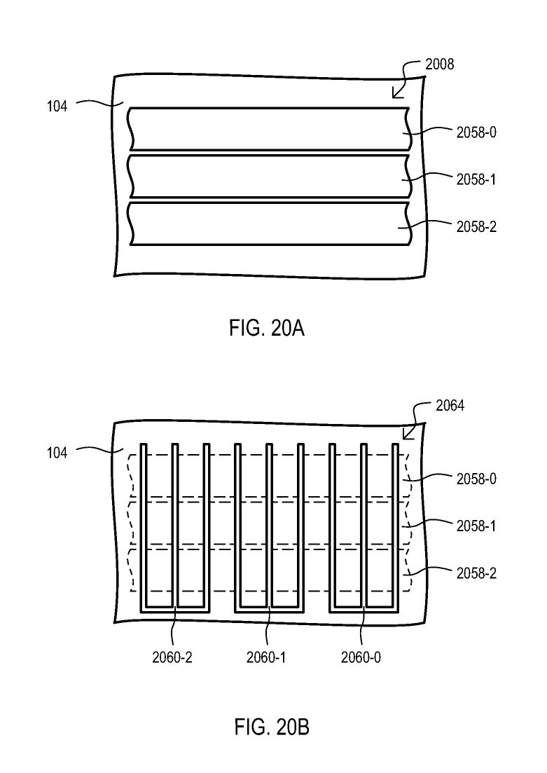

FIGS. 20A and 20B are top plan views showing a method of making a capacitance sensing system according to another embodiment. Referring to FIG. 20A, a first conductive pattern 2008 can be formed on first surface 104 as described herein, or equivalents. In the embodiment shown, a first conductive pattern 2008 can include first electrodes 2058-0 to -2 that repeat in a first direction. First electrodes (2058-0 to -2) can have a relatively large width (such a width being determined in the vertical direction in FIG. 20A).

Referring to FIG. 20B, following the formation of an insulating layer (not shown), a second conductive pattern 2064 can be formed as described herein, or equivalents. In the embodiment shown, a second conductive pattern 2064 can include second electrodes 2060-0 to -2 that repeat in a second direction. Second electrodes (2060-0 to -2) can have a relatively narrow width (such a width being determined in the horizontal direction in FIG. 20B), as compared to the first electrodes (2058-0 to -2).

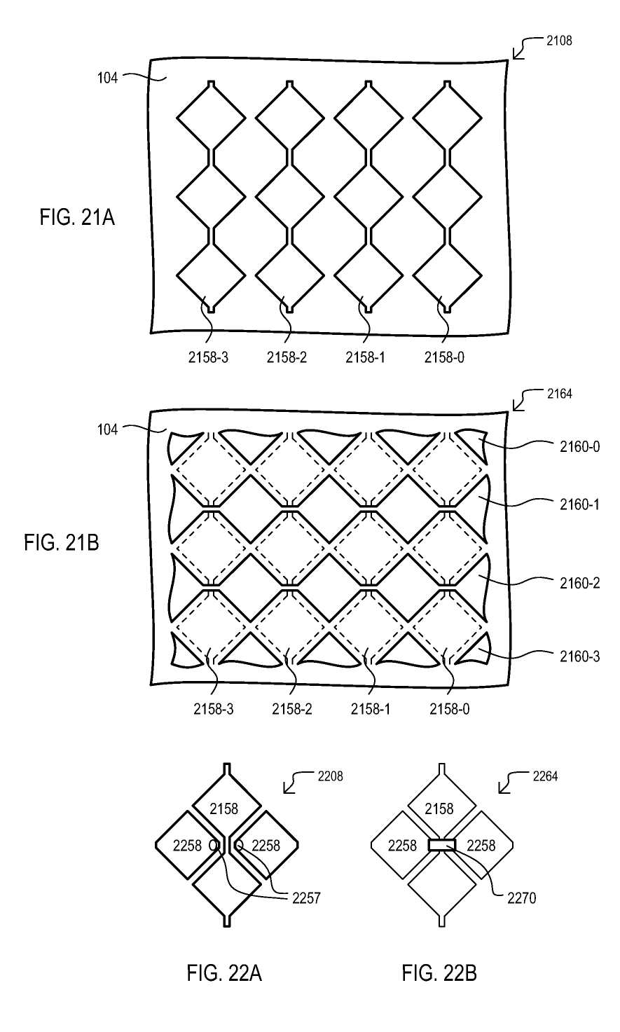

FIGS. 21A and 21B are top plan views showing a method of making a capacitance sensing system according to another embodiment. Referring to FIG. 21A, a first conductive pattern 2108 can be formed on first surface 104 as described herein, or equivalents. In the embodiment shown, a first conductive pattern 2108 can include first electrodes 2158-0 to -3 that repeat in a first direction. First electrodes (2158-0 to -3) can have a repeating diamond pattern.

Referring to FIG. 21B, following the formation of an insulating layer, a second conductive pattern 2164 can be then be formed as described herein, or equivalents. In the embodiment shown, a second conductive pattern 2146 can include second electrodes 2160-0 to -3 that repeat in a second direction. Second electrodes (2160-0 to -3) can have a repeating diamond pattern that crosses over first electrodes (2158-0 to -3) of first conductive pattern 2108.

FIGS. 22A and 22B show an alternate diamond pattern capacitance sensing structure that can be included in the embodiments. Referring to FIG. 22A, a first conductive pattern 2208 can include first electrodes 2158 like those labeled as 2158-0 to -3 in FIG. 21A. However, first conductive pattern 2208 can also include separated electrodes 2258 which can have a diamond shape, but be isolated from any other electrodes. Separated electrodes 2258 can have edge regions 2257 adjacent to narrow portions of first electrodes 2158.

Referring to FIG. 22B, following the formation of an insulating layer (not shown) having openings that expose edge regions 2257, a second conductive pattern 2264 can be formed. Second conductive pattern 2264 can include overpass electrode structures 2270 that join separated electrodes 2258 in a direction perpendicular to first electrodes 2158.

It is understood that any of the conductive patterns shown in FIGS. 19A-22B can be repeated in both vertical and horizontal direction to cover a desired surface area. Further, while such embodiments can be formed with two conductive layers, in other embodiments, such patterns can be formed with more than two conductive layers. In addition, the multi-layer conductive patterns of FIGS. 19A-22B are intended to be but examples of numerous conductive patterns that can be employed in capacitance sensing systems described herein.

It is understood that once a last conductive pattern has been formed, a protective coating can be formed over the capacitance sensing structure, to protect it during subsequent manufacturing steps (e.g., transportation, assembly into a device, etc.).

As noted above, conductive patterns formed on a housing surface, as described herein, can include portions that enable connections to capacitance sensing circuits. Embodiments showing connections to capacitance sensing circuits will now be described.

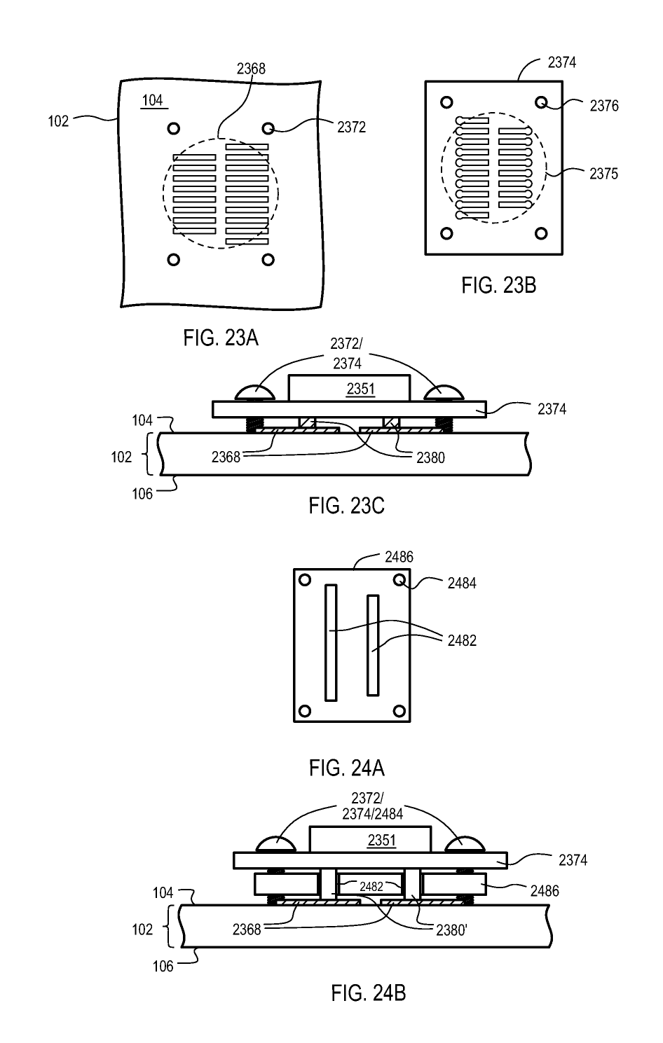

FIG. 23A shows a portion of a housing 102 having connection portions 2368 of a conductive pattern formed on a first surface 104. It is understood that connection portions 2368 are but a small portion of one or more larger conductive patterns (see, for example, FIG. 19C, which shows connection portions 1968/1968′). Optionally, a housing 102 can include mechanical connector structures (one shown as 2372).

FIG. 23B shows a printed circuit board (PCB) 2374 having connection traces 2375 formed thereon. Connection traces 2375 can provide a conductive path to one or more integrated circuit (IC) devices containing capacitance sensing circuits. In one embodiment, such IC device(s) can be mounted on the PCB 2374 on side opposite to that shown in FIG. 23B.

PCB 2374 is in sharp contrast to conventional approaches like that of FIGS. 26 and 27. PCB 2374 does not include traces that serve as capacitance sensors, and so is significantly smaller than a circuit board utilized in a conventional approach. As in the case of FIG. 23A, optionally, a PCB 2374 can include mechanical connector structures (one shown as 2376).

FIG. 23C shows PCB 2374 mounted to housing 102 by vertical conductors 2380. Vertical conductors 2380 can provide a conductive path between connection traces 2375 (of the PCB 2374) and connection portions 2368 (of a conductive pattern for capacitance sensing). In one embodiment, vertical conductors 2380 can be formed from a conductive adhesive, and thus provide both mechanical attachment and electrical connection to connection portions 2368. In one very particular embodiment, vertical connectors 2380 can be formed from an anisotropic conductive adhesive (ACA). As noted above, an IC device 2351 containing capacitance sensing circuits can be attached to PCB 2374.

In some embodiments vertical conductors 2380 can provide the mechanical attachment between connection portions 2368 and connection traces 2370. However, as noted above, in alternate embodiments, additional mechanical connections can be made between PCB 2374 and housing 102 by way of mechanical connector structures (e.g., 2372, 2374). Such mechanical connector structures (e.g., 2372, 2374) can secure PCB 2374 to housing 102 and help ensure that connection portions 2368 remain aligned with connection traces 2370. Mechanical connector structures (e.g., 2372, 2374) can take any suitable form, including but not limited to, screws, threaded inserts, plastic pegs, or bosses.

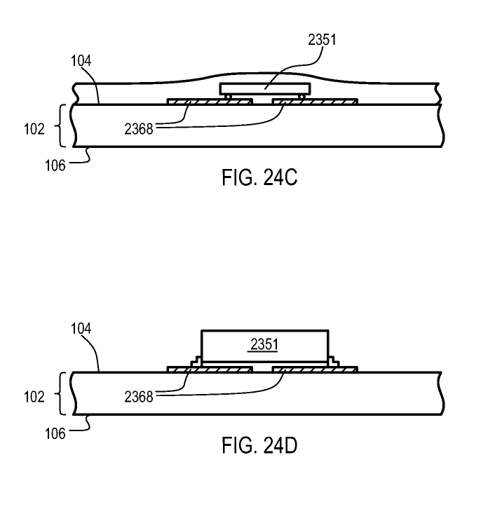

While FIGS. 23A to 23C show embodiments that can include vertical conductors formed with a conductive adhesive, alternate embodiments can include conductive elastomeric connectors. In such embodiments, a spacer can be included to align the elastomeric connector with respect to a conductive pattern and corresponding circuit board traces. Such an embodiment is shown in FIGS. 24A and 24B.

FIG. 24A shows a spacer 2486 having openings 2482 formed therein. A spacer 2486 can include a mechanical connector structures (one shown 2484).

FIG. 24B shows PCB 2374 mounted to housing 102 by elastomeric vertical conductors 2380′. Spacer 2486 can be situated between PCB 2374 and housing 102. Openings 2482 within spacer 2486 can ensure vertical connectors 2380′ are properly aligned between connection portions 2368 and circuit traces of a PCB 2374. Elastomeric vertical conductors 2380′ can require pressure in order to provide good electrical contact, accordingly, mechanical connector structures (e.g., 2372, 2374, 2484) can be used to ensure such pressure exists. As noted above, mechanical connector structures (e.g., 2372, 2374, 2484) can take any suitable form, including but not limited to, screws, threaded inserts, plastic pegs, or bosses.

It is understood that after a PCB has been mounted to a housing, the resulting assembly could be covered with a protective coating.

While embodiments above have shown capacitance sensing systems in which capacitance sensing circuits can be mounted in a PCB, in alternate embodiments, such circuits can be directly mounted on a conductive pattern formed on a housing surface.

Referring to FIG. 24C, a connection portion 2368 of a conductive pattern can be formed by plating with a suitable material, such as copper and/or gold. An integrated circuit 2351 in die form can be bonded to such connection portions. Integrated circuit 2351 includes capacitance sensing circuits.

Referring to FIG. 24D, alternatively, an integrated circuit 2351 in packaged form could have its physical connectors (e.g., leads, pins, landings, etc.) attached to the connection portions 2368 of the conductive pattern(s). Integrated circuit 2351 includes capacitance sensing circuits.

While embodiments can include capacitance sensing systems formed on, or within, a housing wall of an electronic device, other embodiments can include electronic devices employing such systems. Such embodiments will now be described.

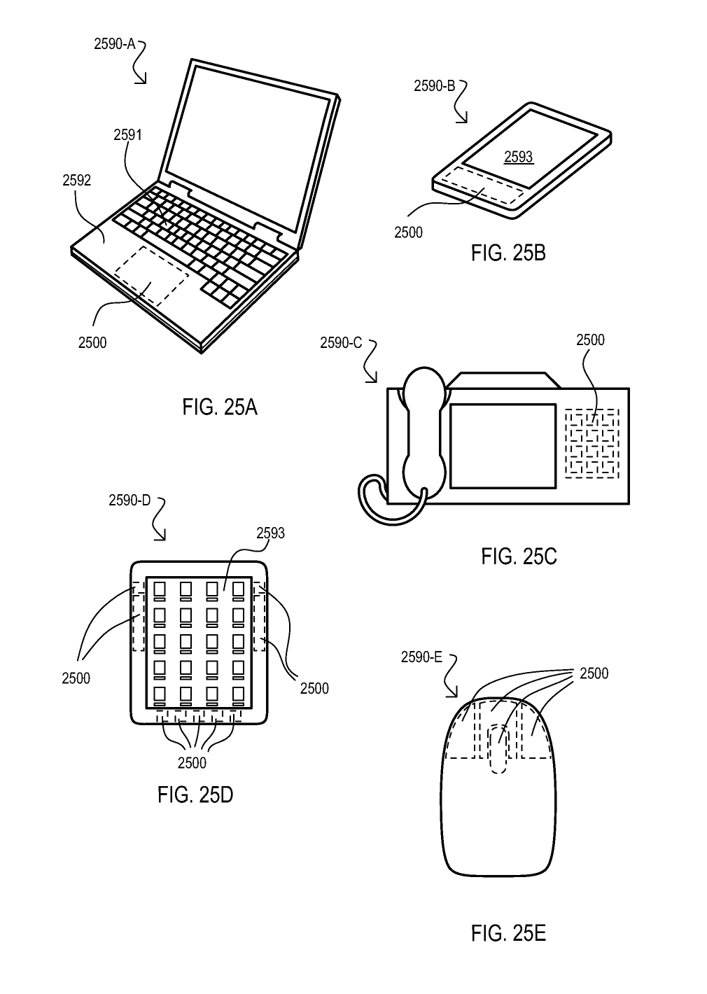

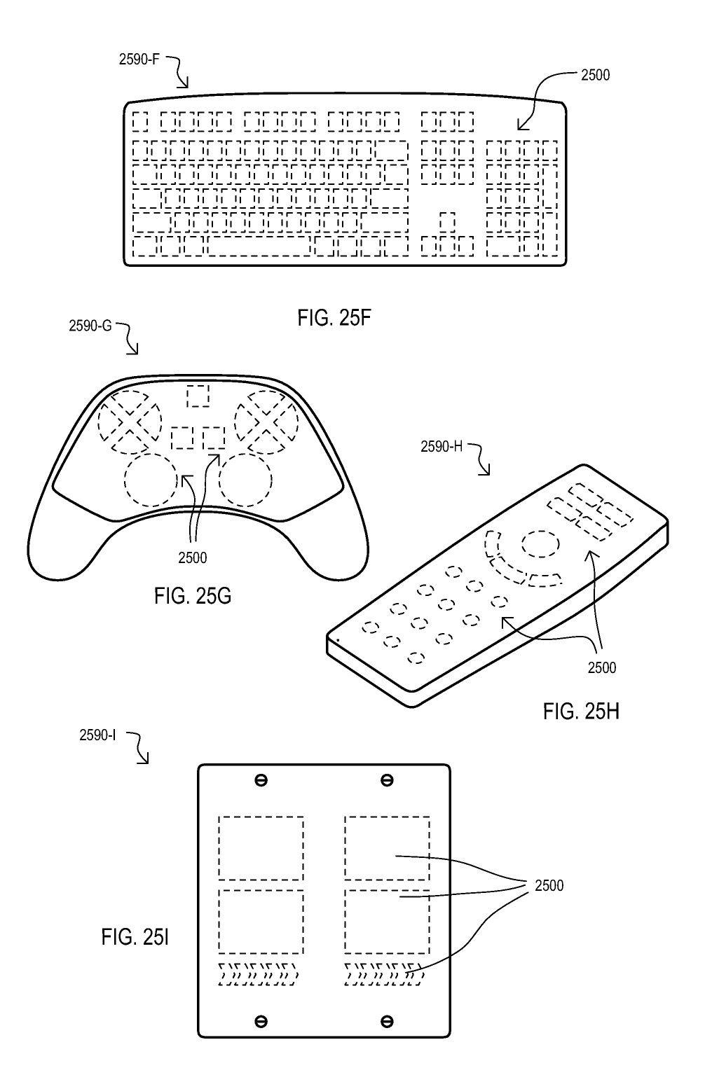

Referring to FIG. 25A, an electronic system according to an embodiment can include a laptop computer 2590-A having a palm rest area 2592 next to a keyboard 2591. All or a portion of palm rest area 2592 can form a housing portion of a capacitance sensing system 2500 as described herein, or equivalents.

Referring to FIG. 25B, an electronic system according to another embodiment can include a cell phone or similar device 2590-B having a touch screen display 2593. All or a portion of the region peripheral to the display 2593 can form a housing portion of a capacitance sensing system 2500 as described herein, or equivalents.

Referring to FIG. 25C, an electronic system according to another embodiment can include a telephone system 2590-C. All or a portion of the housing for the device can form a housing portion of a capacitance sensing system 2500 as described herein, or equivalents.

Referring to FIG. 25D, an electronic system according to another embodiment can include a tablet computing device 2590-D. A tablet computing device 2590-D can include a touch screen display 2593. As in the case of FIG. 25B, all or a portion of the peripheral region can form a housing portion of a capacitance sensing system 2500 as described herein, or equivalents.

Referring to FIG. 25E, an electronic system according to another embodiment can include a human interface device (HID) 2590-E, which in the embodiment shown, can be a computer mouse. All or a portion of HID housing can be a housing portion of a capacitance sensing system 2500 as described herein, or equivalents. In some embodiments, a HID 2590-E can have one contiguous surface, dispensing with the need for mechanical buttons and/or wheels.

Referring to FIG. 25F, an electronic system according to another embodiment can include a computer keyboard 2590-F. All or a portion of a surface of the keyboard can be a housing portion of a capacitance sensing system 2500 as described herein, or equivalents. In some embodiments, keyboard 2590-F can have one contiguous surface, dispensing with mechanical buttons.

Referring to FIG. 25G, an electronic system according to another embodiment can include a gaming controller 2590-G. All or a portion of a surface of the controller 2590-G can be a housing portion of a capacitance sensing system 2500 as described herein, or equivalents.

Referring to FIG. 25H, an electronic system according to another embodiment can include a remote control device 2590-H. All or a portion of a surface of the remote control can be a housing portion of a capacitance sensing system 2500 as described herein, or equivalents.

Referring to FIG. 25I, an electronic system according to another embodiment can include a light switch assembly 2590-I. All or a portion of a face plate for can be a housing portion of a capacitance sensing system 2500 as described herein, or equivalents.

Embodiments described herein can provide for more compact (e.g., thinner) devices, and thus improvements in aesthetics of a device. Large circuit board based assemblies, such as those utilized in conventional devices, can be replaced by electrodes formed on a housing surface, reducing the space needed for electronics.

Embodiments described herein can provide for greater functionality than conventional approaches. Touch areas can be programmable, in both size and function. For example, in one configuration, a housing surface may function in a touchpad fashion. However, in an alternate configuration, the same housing surface may serve as multiple input buttons. In addition or alternatively, embodiments can provide larger area touch surfaces, not being limited to an assembly size, but rather the size and configuration of a housing surface.

It should be appreciated that in the foregoing description of exemplary embodiments, various features are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

It is also understood that the embodiments of the invention may be practiced in the absence of an element and/or step not specifically disclosed. That is, an inventive feature of the invention may be elimination of an element.

Accordingly, while the various aspects of the particular embodiments set forth herein have been described in detail, the present invention could be subject to various changes, substitutions, and alterations without departing from the spirit and scope of the invention.

What is claimed is:

1. A capacitance sensing system, comprising:
at least a first conductive pattern formed on a first surface of a housing of an electronic device; and
a capacitance sensing circuit electrically connected to the first conductive pattern.

2. The capacitance sensing system of claim 1, wherein:
the first conductive pattern is selected from the group of: a conductive ink printed on the first surface, a patterned foil, an etched layer of metal, and a stamped layer of metal.

3. The capacitance sensing system of claim 1, wherein:
the first conductive pattern has direct contact with the first surface.

4. The capacitance sensing system claim 1, wherein:
the first conductive pattern is embedded into the first surface.

5. The memory device of claim 1, wherein:
the housing comprises at least one housing wall; and
the first conductive pattern is formed inside the housing wall.

6. The capacitance sensing system of claim 1, further including:
an adhesive material formed between the first conductive pattern and the first surface.

7. The capacitance sensing system of claim 1, further including:
at least one attachment mechanism that mechanically attaches the first conductive pattern to the first surface.

8. The capacitance sensing system of claim 1, wherein:
the first conductive pattern includes first shapes repeated in a first direction.

9. The capacitance sensing system of claim 8, wherein:
the first conductive pattern further includes at least one second shape interleaved with the first shapes.

10. The capacitance sensing system of claim 1, further including:
a second conductive pattern formed over the first conductive pattern.

11. The capacitance sensing system of claim 10, wherein:
the second conductive pattern is separated from the first conductive pattern by an insulator.

12. The capacitance sensing system of claim 1, wherein:
the capacitance sensing circuit includes
at least a first integrated circuit coupled to a circuit board having conductive traces formed thereon, the circuit board being disposed over the first surface, and
a plurality of vertical connectors coupled between the circuit board traces and the first conductive pattern.

13. The capacitance sensing system of claim 12, wherein:
the vertical connectors are selected from the group of: anistropic conductive adhesive structures, non-anistropic conductive adhesive structures, and elastomeric connectors.

14. The capacitance sensing system of claim 1, further including:
the first surface is an inner surface of the housing.

15. A method, comprising:
placing at least a first conductive pattern on a first surface of a housing of an electronic device; and
electrically connecting the first conductive pattern to inputs of a capacitance sensing circuit.

16. The method of claim 15, wherein:
placing the first conductive pattern on the first surface includes a subtractive process comprising
forming a conductive layer, and
removing portions of the conductive layer to form the first conductive pattern.

17. The method of claim 16, wherein:
removing portions of the conductive layer to form the first conductive pattern includes steps selected from the group of: chemical etching, plasma etching, laser removal, and mechanical removal.

18. The method of claim 15, wherein:
placing the first conductive pattern on the first surface includes an additive process that deposits at least one conductive material in a shape of at least a portion of the first conductive pattern.

19. The method of claim 18, wherein:
the additive process includes printing a conductive ink on the first surface.

20. The method of claim 15, wherein:
placing the first conductive pattern includes attaching a pre-formed first conductive pattern on the first surface.

21. An electronic device, comprising:
a housing surrounding electronic components with a housing wall having at least a first surface; and
at least a first conductive pattern formed on the first surface; wherein
the electronic components include a capacitance sensing circuit having a conductive connection to the first conductive pattern.

22. The electronic device of claim 21, wherein:
the first conductive pattern is selected from the group of: a printed conductive ink, a deposited conductive material, a pre-patterned metallic layer, and a pre-patterned foil layer.

23. The electronic device of claim 21, wherein:
the first conductive pattern includes connections portions; and
the capacitance sensing circuit comprises
a circuit board physically attached to the first surface having conductive traces, and
vertical conductors oriented substantially perpendicular to the first surface that conductively connect the connection portions to the conductive traces.

24. The electronic device of claim 21, wherein:
the housing includes an outer user surface opposite to the first surface for receiving capacitive sensing inputs for the electronic device.

25. The electronic device of claim 24, wherein:
the user surface includes user indications formed thereon that identify the user surface from other portions of the outer surface.

26. The electronic device of claim 21, wherein:
the electronic device comprises a computing device with a keyboard, and
the housing wall comprises a palm rest area adjacent to the keyboard.

27. The electronic device of claim 21, wherein:
the electronic device comprises an electronic display, and
the housing wall comprises an area peripheral to the electronic display.

28. The electronic device of claim 21, wherein:
the electronic device comprises a human interface device for a computing system.

29. The electronic device of claim 21, wherein:
the electronic device comprises a touch switch for an electrical system.
